(19) United States
(12) Patent Application Publication
(10) Pub. No.: US 2002/0096700 A1
(43) Pub. Date: Jul. 25, 2002

(54) Non-volatile semiconductor memory device and method of manufacturing the same

(76) Inventor: Tatsuro Inoue, Tokyo (JP)

Correspondence Address: Darryl G. Walker, WALKER & SAKO, LLP, Suite 235, 300 South First Street, San Jose, CA, 95113, US

(21) Appl. No.: 10/051,600

(22) Filed: Jan. 18, 2002

(30) Foreign Application Priority Data
Jan. 22, 2001 (JP) 2001-012933

(51) Int. Cl. H01L 29/76

(52) U.S. Cl. 257/296

(57) ABSTRACT

A non-volatile semiconductor memory device including a memory cell transistor in a memory cell region (10a) and a peripheral transistor in a peripheral region (10b) on the same substrate has been disclosed. A metal silicide layer (28) may be included on a source/drain region (26) and a control gate (15) of a peripheral transistor and a source region (24) and a drain region (23) of a memory cell transistor. A cell contact hole (31) may be formed to provide an electrical connection to drain region (23) of a memory cell transistor. Cell contact hole (31) may be self-aligned. In this way, a cell area of a memory cell may be reduced and a resistance of the peripheral transistor may be reduced.

### TECHNICAL FIELD

The present invention relates generally to a non-volatile semiconductor memory device and more particularly to a non-volatile semiconductor memory device that may be used in a flash memory and a manufacturing method thereof.

### BACKGROUND OF THE INVENTION

In order to reduce costs and/or provide semiconductor memories having a higher density, it is a continuing goal to reduce chip area consumed by each memory cell on a semiconductor memory device. One type of semiconductor memory device is a non-volatile semiconductor memory device, such as a flash memory. A manufacturing method of a conventional non-volatile semiconductor memory device for use in a flash memory will be described with reference to FIGS. 8 to 10.

FIGS. 8 to 10 are sectional views illustrating steps of a conventional flash memory process for the manufacture of a conventional non-volatile semiconductor memory device.

Referring now to FIG. 8(a), an element isolation region 1a is formed on a surface of a semiconductor substrate 1. Then, a tunnel oxide film 2 and a first polycrystalline silicon film 3a are formed. The first polycrystalline silicon film 3a is patterned while covering only predetermined portions in a memory cell region with a resist mask (not shown). Thus, a peripheral transistor region Tr is exposed.

Referring now to FIG. 8(b), after removing the resist mask, a multi-layer film 4b is formed as a second gate insulating film over the entire surface. The multi-layer film 4b consists of an oxide film, a nitride film, and another oxide film. Using a resist film 5a as a mask covering only the memory cell region, the multi-layer film 4b and the tunnel oxide film 2 are removed from the peripheral transistor region Tr.

Referring now to FIG. 8(c), after the resist film 5a is removed, a gate oxide film 4a is formed in the peripheral transistor region Tr. A second polycrystalline silicon film 3b is then formed over the entire surface.

Referring now to FIG. 8(d), the first polycrystalline film 3a, multi-layer film 4b, and polycrystalline silicon film 3b are patterned using a resist film 5b as a mask. In this way, a gate electrode having a multi-layer structure is formed.

Referring now to FIG. 9(e), a resist mask 5c that covers the entire surface is patterned and etched to form the second polycrystalline film 3b in the peripheral transistor region Tr.

Referring now to FIG. 9(f), the entire surface is then coated with a resist film, which is patterned to form resist film 5d over the peripheral transistor region Tr. Drain regions 6a and source regions 6b are then formed using resist film 5d and second polysilicon film 3b in memory cell region as a mask.

Referring now to FIG. 9(g), the entire surface is then coated with a resist film, which is patterned to form resist film 5e over the memory cell region. A drain region 6c and a source region 6d in the peripheral transistor region Tr is then formed using resist film 5e and second polycrystalline film 3b in the peripheral transistor region Tr as a mask.

Referring now to FIG. 9(h), after the resist film 5e is removed, a first nitride film 7 is formed and subjected to an etch back using plasma. In this way, first nitride film 7 is left as side walls at side faces of gate electrodes in the peripheral transistor region Tr and the memory cell region.

Referring now to FIG. 10(i), the entire surface is then sputtered with Ti or W and subjected to heat treatment to generate silicide. Silicide layers 8 are thus formed by a salicide process on the gate electrodes and source drain/regions in the peripheral transistor region Tr and memory cell region.

Referring now to FIG. 10(j), after an interlayer insulating film 9 made from a silicon oxide film is formed, contact holes 9a are formed on the source/drain regions in the peripheral transistor region Tr and in the memory cell region. The contact holes 9a pierce through the interlayer insulating film 9 to the source drain regions.

Referring now to FIG. 10(k), metal plugs 9b are formed by sputtering CVD (chemical vapor deposition), etc. using a metal such as W (tungsten), which is used to fill contact holes 9a. Additionally, metal wiring lines 9c connected to the metal plugs 9b are formed.

Thus, the conventional non-volatile semiconductor memory device for use in a flash memory is thus manufactured.

In the conventional flash memory process described above, a self-aligned contact cannot be formed to provide a contact to a drain contact because the silicide layers are formed by a salicide process on the gate electrodes in the peripheral transistor region Tr and memory cell region. In order to be formed a self-aligned contact to provide a contact a drain contact, a nitride film must be formed on the gate electrodes and the silicide layers cannot be formed on the gate electrodes. Therefore, the gate electrodes in the peripheral transistor region Tr are high in resistance and the operation speed of the peripheral transistor is slow in low voltage.

In view of the above discussion, it would be desirable to provide a non-volatile semiconductor memory device that may be capable of reducing the cell area while providing a peripheral transistor to have a gate electrode of a low resistance. It would also be desirable to provide a manufacturing method of the non-volatile semiconductor memory device.

### SUMMARY OF THE INVENTION

According to the present embodiments, a non-volatile semiconductor memory device may include a memory cell transistor in a memory cell region and a peripheral transistor in a peripheral region on the same substrate. A metal silicide layer may be included on a source/drain region and a control gate of the peripheral transistor and a source region and drain region of the memory cell transistor. A cell contact hole may be formed to provide an electrical connection to the drain region of the memory cell transistor. The cell contact hole may be self-aligned. In this way, the cell area of a memory cell may be reduced and the resistance of the peripheral transistor may be reduced.

According to one aspect of the embodiments, a non-volatile semiconductor memory device may include a memory cell transistor and a peripheral transistor on the same substrate. A metal silicide layer may be formed on at least one diffusion layer of the memory cell transistor, at least one diffusion layer of the peripheral transistor and a gate electrode of the peripheral transistor. A self aligned contact structure may provide an electrical connection to the at least one diffusion layer of the memory cell transistor.

According to another aspect of the embodiments, the gate electrode of the peripheral transistor and a floating gate electrode of the memory cell transistor may be formed from the same material.

According to another aspect of the embodiments, a gate insulating film may be formed under the gate of the peripheral transistor. A floating gate insulating film may be formed under a floating gate electrode of the memory cell transistor. The gate insulating film may be thicker than the floating gate insulating film.

According to another aspect of the embodiments, the self aligned contact structure may include a conductive plug. The conductive plug may include a conductive plug portion at least partially overlapping a memory cell gate electrode of the memory cell transistor.

According to another aspect of the embodiments, an element separation region may be disposed between the peripheral transistor and the memory cell transistor.

According to another aspect of the embodiments, the metal silicide layer may include cobalt.

According to another aspect of the embodiments, a method of manufacturing a non-volatile semiconductor memory device having a memory cell transistor and a peripheral transistor on the same substrate may include a metal silicide layer formed on at least one diffusion layer of the memory cell transistor and at least one diffusion layer of the peripheral transistor at essentially the same time. A self aligned contact may then be formed to provide an electrical connection to the at least one diffusion layer of the memory cell transistor.

According to another aspect of the embodiments, a contact hole to provide an electrical connection to the at least one diffusion layer of the peripheral transistor may be formed at essentially the same time as the self aligned contact.

According to another aspect of the embodiments, the memory cell transistor may include a floating gate and a memory cell transistor control gate. The self aligned contact may include a conductive plug including a conductive plug portion at least partially overlapping the memory cell transistor control gate.

According to another aspect of the embodiments, a side wall insulating film may be formed on a side of the memory cell transistor control gate.

According to another aspect of the embodiments, a method of manufacturing a non-volatile semiconductor memory device having a memory cell transistor and a peripheral transistor on a semiconductor substrate may include the steps of forming an element separation region on the semiconductor substrate, forming a first gate oxide film in a memory cell transistor region and a peripheral transistor region, forming a peripheral transistor gate electrode and a memory cell transistor floating gate electrode, forming an inter-electrode insulating film over the floating gate electrode, forming a memory cell transistor control gate electrode over the inter-electrode insulating film, forming a first nitride film over the memory cell transistor control gate electrode, forming a peripheral diffusion electrode for the peripheral transistor and a memory cell diffusion electrode for the memory cell transistor, forming a second nitride film as side walls on the side faces of the memory cell transistor control gate electrode, forming metal silicide layers on the peripheral transistor gate electrode and peripheral transistor diffusion electrode, sequentially forming a third nitride film and an interlayer insulating film over the memory cell transistor region and peripheral transistor region, and removing portions of the interlayer insulating film and the third nitride film that are over the memory cell diffusion electrode to open a memory cell contact hole.

According to another aspect of the embodiments, forming the peripheral transistor gate electrode and the memory cell transistor floating gate may include forming a first polycrystalline silicon film over the surface and patterning the first polycrystalline silicon film so as to separate the peripheral transistor region from the memory cell transistor region.

According to another aspect of the embodiments, the steps of forming the interlayer insulating film, forming the memory cell transistor control gate electrode and forming the first nitride film may include forming the inter-electrode film, a second polycrystalline silicon film, and the first nitride film in that order on the semiconductor substrate and etching the first nitride film, second polycrystalline film, and inter-electrode insulating film to form the memory cell transistor gate electrode.

According to another aspect of the embodiments, forming the memory cell transistor floating gate may include etching the first polycrystalline silicon film in the memory cell transistor region in the step of etching the first nitride film, second polycrystalline film, and inter-electrode insulating film.

According to another aspect of the embodiments, the second polycrystalline silicon film may contain an impurity.

According to another aspect of the embodiments, forming the peripheral diffusion electrode and the memory cell diffusion electrode may include a heat treatment.

According to another aspect of the embodiments, forming the peripheral transistor gate electrode may include etching the first polycrystalline film in the peripheral transistor region separately from etching the first polycrystalline film in the memory cell transistor region.

According to another aspect of the embodiments, removing portions of the interlayer insulating film and the third nitride layer may include removing portions of the interlayer insulating film and the third nitride layer over the peripheral transistor diffusion electrode to open a peripheral contact hole.

According to another aspect of the embodiments, the method of manufacturing a non-volatile semiconductor memory device may include the step of forming a second gate oxide film on the first gate oxide film in the peripheral transistor region while substantially leaving the first gate oxide film in the memory cell region.

According to another aspect of the embodiments, the non-volatile semiconductor memory may be a flash memory.

### BRIEF DESCRIPTION OF THE DRAWINGS

FIG. 1 is a sectional view illustrating steps of a process for the manufacture of a non-volatile semiconductor memory device according to one embodiment.

FIG. 2 is a sectional view illustrating steps of a process for the manufacture of a non-volatile semiconductor memory device according to one embodiment.

FIG. 3 is a sectional view illustrating steps of a process for the manufacture of a non-volatile semiconductor memory device according to one embodiment.

FIG. 4 is a sectional view illustrating steps of a process for the manufacture of a non-volatile semiconductor memory device according to another embodiment.

FIG. 5 is a sectional view illustrating steps of a process for the manufacture of a non-volatile semiconductor memory device according to another embodiment.

FIG. 6 is a sectional view illustrating steps of a process for the manufacture of a non-volatile semiconductor memory device according to another embodiment.

FIG. 7(a) is a plan view of a portion of a memory cell region of a non-volatile semiconductor memory device manufactured by a method according to an embodiment of the present invention.

FIG. 7(b) is a plan view of a portion of a memory cell region of a conventional non-volatile semiconductor memory device manufactured by a conventional manufacturing method.

FIG. 8 is a sectional view illustrating steps of a conventional flash memory process for the manufacture of a conventional non-volatile semiconductor memory device.

FIG. 9 is a sectional view illustrating steps of a conventional flash memory process for the manufacture of a conventional non-volatile semiconductor memory device.

FIG. 10 is a sectional view illustrating steps of a conventional flash memory process for the manufacture of a conventional non-volatile semiconductor memory device.

### DETAILED DESCRIPTION OF THE EMBODIMENTS

Various embodiments of the present invention will now be described in detail with reference to a number of drawings.

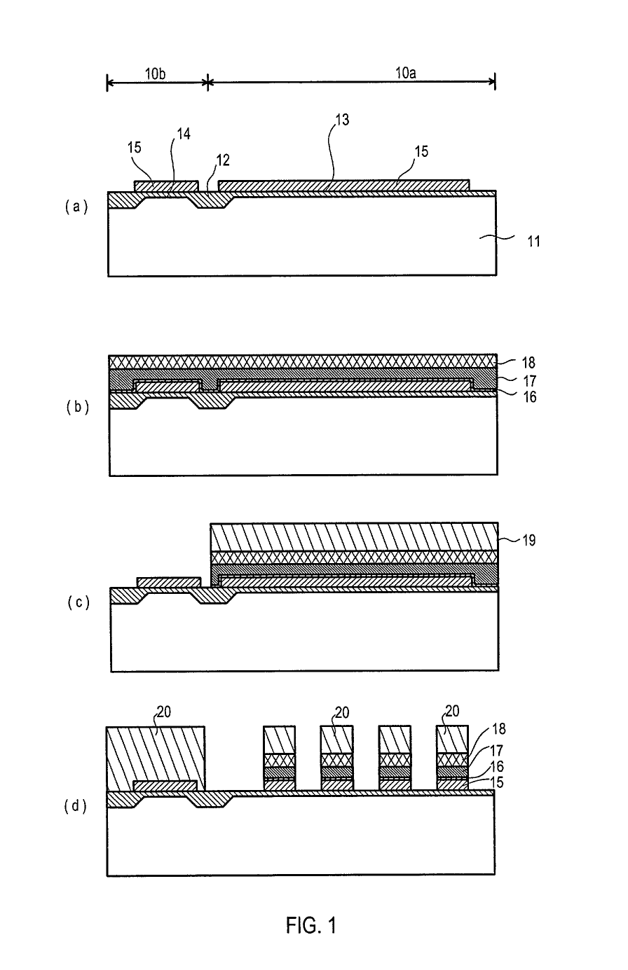

FIGS. 1 to 3 are sectional views illustrating steps of a process for the manufacture of a non-volatile semiconductor memory device according to one embodiment.

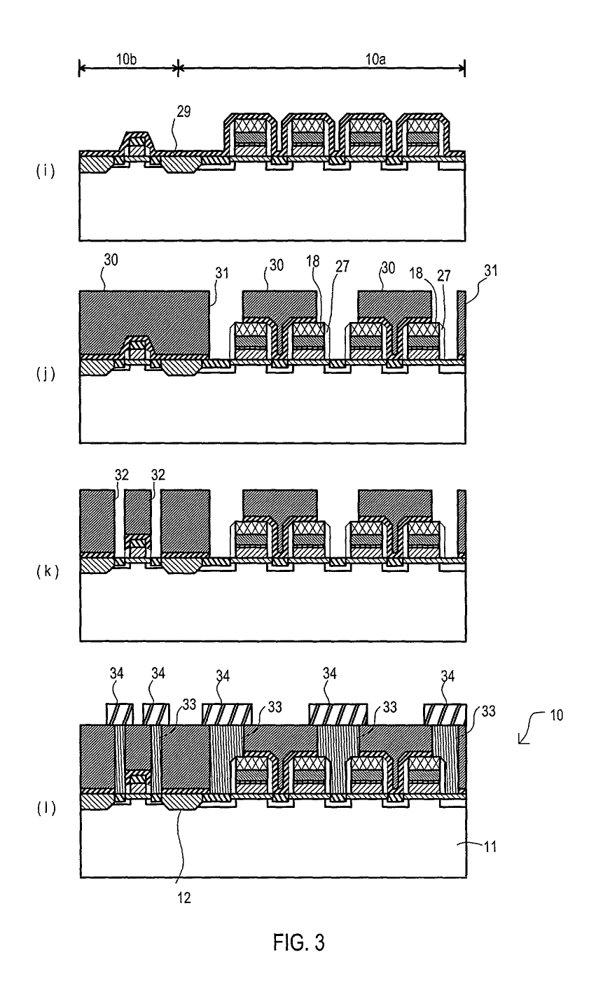

Referring now to FIG. 3(l), a non volatile semiconductor memory device 10 may include a memory cell transistor formed in a memory cell region 10a and a peripheral transistor formed in a peripheral transistor region 10b. A peripheral transistor may be separated from the memory cell transistor by an element separation region 12 on a semiconductor substrate 11.

Referring now to FIG. 1(a), first, an element separation region may be formed on a surface of the semiconductor substrate 11 using, for example, an existing technique. A semiconductor substrate 11 may be a p-type semiconductor substrate. An element separation region 12 may be a SiO₂ film and may be formed by thermal oxidation to a thickness of about 300 nm by conventional LOCOS (local oxidation of silicon). Alternatively, if a shallow trench isolation (STI) structure is used, a trench may be formed to about 200 nm and an insulating film may be deposited in the trench and polished by a CMP (chemical mechanical polishing) method. Such an insulating film may be formed by a high density plasma (HDP) CVD (chemical vapor deposition) to a thickness of about 400 nm, for example.

After a element separation region 12 is formed, a first gate oxide film (tunnel insulating film) 13 may be formed in a memory cell region 10a where a memory cell transistor is to be formed. A first gate oxide film 13 may include a SiO₂ film having a thickness of about 9 nm. A second gate oxide film 14 may then be formed in a peripheral transistor region 10b where a peripheral transistor is to be formed. A second gate oxide film 14 may be a SiO₂ film having a thickness of about 5 nm. The steps for forming the films may include lithography and etching.

It is noted that a first gate oxide film 13 may be formed in a peripheral transistor region 10b. After a first gate oxide film 13 is formed, a second gate oxide film 14 may be additionally formed by forming another oxide film on a first gate oxide film 13 in a peripheral transistor region 10b without substantially affecting a first gate oxide film 13 in a memory cell region 10a. Thus, a gate oxide films (13 and 14) may be formed in a memory cell region 10a and a peripheral transistor region 10b. If necessary, second gate oxide films 14 with varying thickness may be formed.

A first polysilicon film 15 may then be formed in a memory cell region 10a and a peripheral transistor region 10b. Polycrystalline silicon film 15 may be polycrystalline silicon having a thickness of about 100 nm and may be formed using a CVD method, for example. After that a resist or other patterning mask may be used in patterning to provide polycrystalline film 15 separated between a memory cell region 10a and a peripheral transistor region 10b. A first polycrystalline film 15 in a memory cell region may include an impurity such as phosphorus. A resist and/or other patterning mask may be removed as soon as the etching is completed.

Referring now to FIG. 1(b), next, an inter-electrode insulating film 16 may be formed in a memory cell region 10a. A inter-electrode insulating film 16 may be formed with a CVD method so as to cover a first polycrystalline silicon film 15. Inter-electrode insulating film 16 may be about a 15 nm thick ONO (oxide nitride oxide) film that includes a three-layer structure consisting of a SiO₂ film, a Si₃N₄ film, and another SiO₂ film.

Still referring to FIG. 1(b), a inter-electrode insulating film 16 may then be covered with a second polycrystalline silicon film 17. A second polycrystalline silicon film 17 may include, for example, an about 50 nm thick polycrystalline silicon film containing phosphorus as an impurity and an about 100 nm thick polycrystalline silicon film formed with WSi. A second polycrystalline film 17 may be formed using a CVD method. Additionally, a second polycrystalline silicon film 17 may be covered with a first nitride film 18. A first nitride film 18 may be formed with a CVD method from a nitride to a thickness of about 200 nm, for example.

An inter-electrode insulating film 16, a second polycrystalline silicon film 17, and a first nitride film 18 may be formed on a semiconductor substrate 11 in the order stated. A second polycrystalline silicon film 17 may function as a control gate of a memory cell transistor.

Referring now to FIG. 1(c), patterning may be conducted while covering only a memory cell region 10a with a resist 19 or other patterning mask so as to leave a first nitride film 18, a second polycrystalline silicon film 17, and a inter-electrode insulating film 16 in a memory cell region 10a. In this way, a first polycrystalline silicon film 15 in a peripheral transistor region 10b may be exposed.

Referring now to FIG. 1(d), a memory cell region 10a and a peripheral transistor region 10b may be patterned while using a resist 20 or other patterning mask. In this way, in a memory cell region 10a, only portions including control gate electrodes may remain masked. Exposed portions of first nitride film 18, second polycrystalline silicon film 17, inter-electrode insulating film 16, and first polycrystalline silicon film 15 in memory cell region 10a may be sequentially removed by dry etching using a RIE (reactive ion etching) technique, for example. After etching is completed, resist 20 may be removed.

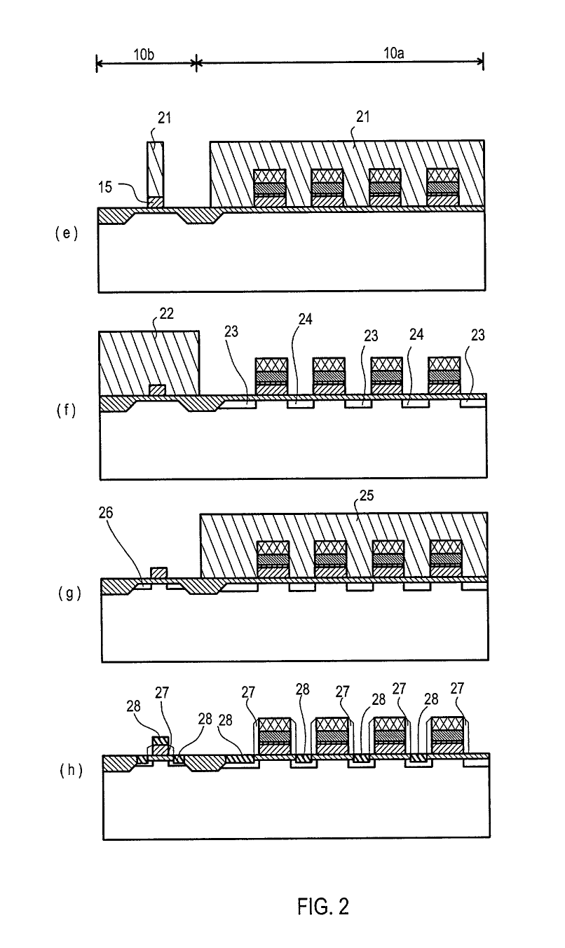

Referring now to FIG. 2(e), memory cell region 10a and peripheral transistor region 10b may be patterned while using a resist 21 or other patterning mask. In this way, in peripheral transistor region 10b, only portions including control gate electrodes may remain masked. Exposed portions of first polycrystalline silicon film 15 in peripheral transistor region 10b may be removed, for example, by dry etching using a RIE technique. After etching is completed, resist 21 may be removed.

Referring now to FIG. 2(f), a resist 22 or other patterning mask may be patterned so as to expose only memory cell region 10a while covering peripheral transistor region 10b. Impurities may be introduced in memory cell region 10a by an ion implantation technique. In this way, drain regions 23 and source regions 24 may be formed in memory cell region 10a. After ion implantation is completed, resist 22 may be removed.

Referring now to FIG. 2(g), a resist 25 or other patterning mask may be patterned so as to expose only peripheral transistor region 10b while covering memory cell region 10a. Impurities may be introduced in peripheral transistor region 10b by an ion implantation technique. In this way, source/drain regions 26 may be formed in peripheral transistor region 10b. After the ion implantation is completed, resist 25 may be removed.

The removal of resist 25 may be followed by annealing. In this way, diffusion layers may be driven or activated in memory cell region 10a and peripheral transistor region 10b.

Referring now to FIG. 2(h), a second nitride film 27 may be formed from a CVD method, for example. Second nitride film 27 may have a thickness of about 200 nm, for example. Second nitride film 27 may be etched back to be left as side walls at side faces of gate electrodes in memory cell region 10a and peripheral transistor region 10b.

Next, an alloy including CoSi (colbalt silicide) may be formed by sputtering, for example. The alloy may have a thickness of about 11 nm. The alloy may then be subjected to annealing several times. Excess CoSi may then be removed. In this way, metal silicide layers 28 may be formed on drain regions 23 and source regions 24 in memory cell region 10a and on source/drain regions 26 and a gate electrode of peripheral transistor region 10b by the salicide process.

Referring now to FIG. 3(i), a third nitride film 29 may be formed over the entire surface of memory cell region 10a and peripheral transistor region 10b so as to cover second nitride film 27 and silicide layers 28. Third nitride film 29 may have a thickness of about 100 nm, for example, and may be formed by a CVD method.

Referring now to FIG. 3(j), an interlayer insulating film 30 may be formed over the entire surface of memory cell region 10a and peripheral transistor region 10b so as to cover third nitride layer 29. Interlayer insulating film 30 may be formed by a CVD method using, for example, a BPSG (boron phospho silicate glass) film having a thickness of about 700 nm.

The surface of interlayer insulating film 30 may be polished by a CMP (chemical mechanical polishing) method, for example. Then, interlayer insulating film 30 and third nitride layer 29 on drain regions 23 of memory cell region 10a may be removed using a RIE technique. In this way, cell contact holes 31 may be formed.

Referring now to FIG. 3(k), a RIE technique or the like may be used to remove the interlayer insulating film 30 and the third nitride layer 29 on the source drain region 26 of the peripheral transistor region 10b. In this way, contact holes 32 may be formed.

Referring now to FIG. 3(l), a barrier metal, such as Ti or TiN, may be sputtered. Then metal plugs 33 may be formed with W (tungsten) by a CMP method or etched back from W or other high melting point metals to fill cell contact holes 31 and contact holes 32. Metal wiring lines 34 may then be formed from aluminum or the like through patterning to be connected to metal plugs 33.

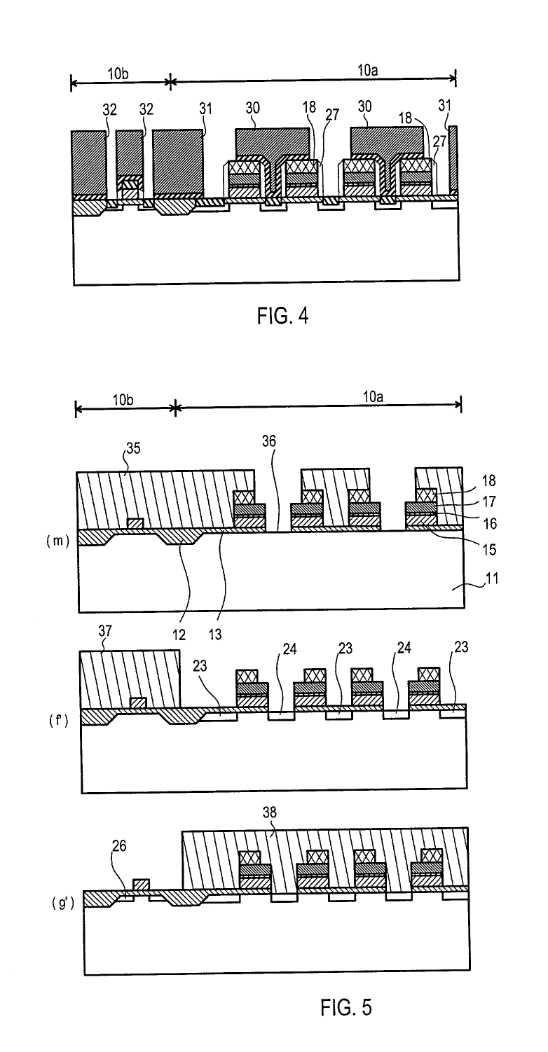

FIG. 4 is a sectional view illustrating steps of a process for the manufacture of a non-volatile semiconductor memory device according to one embodiment. In the embodiment of FIG. 4, contact holes 32 of a peripheral transistor region 10b may be formed at the same time cell contact holes 31 of a memory cell region 10a are formed. The rest of structures and operation may be essentially the same as the manufacturing steps for the non-volatile semiconductor memory device illustrated in FIGS. 1 to 3.

Referring to FIG. 3j), interlayer insulating film 30 may be formed using a CVD method after third nitride layer 29 (FIG. 3(i)) was formed. Interlayer insulating film 30 may be a BPSG film having a thickness of about 700 nm over the entire surface of memory cell region 10a and peripheral transistor region 10b so as to cover third nitride 29. The surface of interlayer insulating film 30 may be polished using a CMP method or the like.

Referring now to FIG. 4, cell contact holes 31 are then formed in memory cell region 10a using a RIE technique or the like. At the same time, contact holes 32 may be formed in peripheral transistor region 10b.

After the simultaneous forming of cell contact holes 31 and contact holes 32, metal plugs 33 may be formed and metal wiring lines 34 may be formed through patterning as illustrated in FIG. 3(l).

Referring once again to FIG. 4, portions of third nitride film 29 may be removed during the formation of cell contact holes 31 and contact holes 32. However, because gate electrodes of memory cell region 10a are covered with first nitride film 18 and second nitride film 27, the removal of third nitride film 29 may not cause a short circuit between metal wiring lines 34 (FIG. 3(l)) which may be formed after removal.

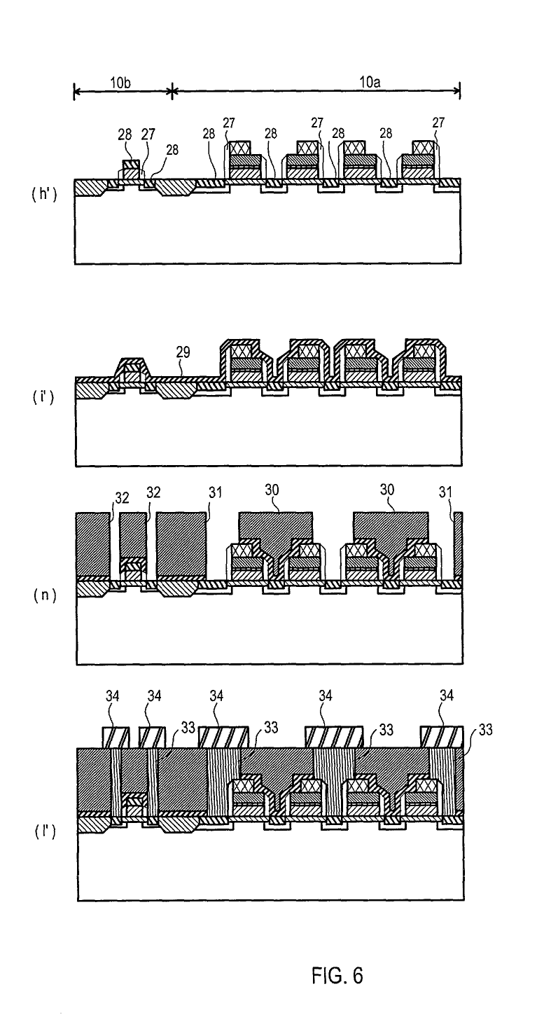

FIGS. 5 and 6 are sectional views illustrating steps of a process for the manufacture of a non-volatile semiconductor memory device according to an embodiment.

In the embodiment of FIGS. 5 and 6, when first gate oxide film 13 in source regions of memory cell region 10a are removed by etching, a resist may be patterned while allowing a margin for pattern misalignment with respect to control gates. The rest of structures and operations may be essentially the same with the previously mentioned manufacturing steps for a non-volatile semiconductor memory device.

As illustrated in FIG. 2(e), in a manufacturing step for a non-volatile semiconductor memory device, portions of first polycrystalline silicon film 15 may be removed in the peripheral transistor region using resist 21 as a mask to leave a gate electrode. Thereafter, a resist (not shown) or other patterning mask may be used in patterning to expose only source regions while covering memory cell region 10a. First gate oxide film 13 in exposed source regions may then be removed by etching.

Referring now to FIG. 5(m), at this point, a resist 35 may be patterned while allowing a margin for pattern misalignment with respect to the control gates of memory cell region 10a.

In this way, after the formation of a gate electrode in peripheral transistor region 10b, a self-alignment process including patterning for removing first gate oxide film 13 in source region forming areas and patterning for forming source regions 24 in memory cell region 10a (FIG. 2(f)) may be simultaneously conducted to form a self-aligned source (SAS) 36. Resist 35 may then be removed.

Referring now to FIG. 5(f′), after self-aligned source 36 is formed and resist 35 is removed, a resist 37 or other patterning mask may be used to expose memory cell region 10a while covering peripheral transistor region 10b. Using an ion implantation technique, impurities may be introduced to apertures of memory cell region 10a to form drain regions 23 and source regions 24 in memory cell region 10a. After ion implantation is completed, resist 37 may be removed.

Referring now to FIG. 5(g′), similarly to FIG. 2(g), patterning may be conducted using a resist 38 to expose only peripheral transistor region 10b. Source/drain region 26 may be formed in peripheral region 10b through ion implantation, for example. Resist 38 may then be removed. Annealing may be conducted to drive or activate diffusion layers of memory cell region 10a and peripheral transistor region 10b.

Referring now to FIG. 6(h′), similarly to FIG. 2(h), a second nitride film 27 may be formed from a nitride by a CVD method and then may be etched back to be left as side walls at side faces of the gate electrodes in memory cell region 10a and peripheral transistor region 10b. Silicide layers 28 may be formed on drain regions 23 and source regions 24 in memory cell region 10a and on source/drain regions 26 and the gate electrode of peripheral transistor region 10b by a salicide process from an alloy including CoSi.

Referring now to FIG. 6(i′), similarly to FIG. 3(i), a third nitride film 29 may be formed, using a CVD method, over the entire surface of memory cell region 10a and peripheral transistor region 10b so as to cover second nitride film 27 and silicide layers 28.

Referring now to FIG. 6(n), similarly to FIG. 4, an interlayer insulating film 30 may be formed by a CVD method over the entire surface of memory cell region 10a and peripheral transistor region 10b. After polishing the surface of interlayer insulating film 30, cell contact holes 31 may be formed in memory cell region 10a. At the same time, contact holes 32 may be formed in peripheral transistor region 10b.

Referring now to FIG. 6(l′), similarly to FIG. 3(l), metal plugs 33 may be formed and metal wiring lines 34 may be formed through patterning.

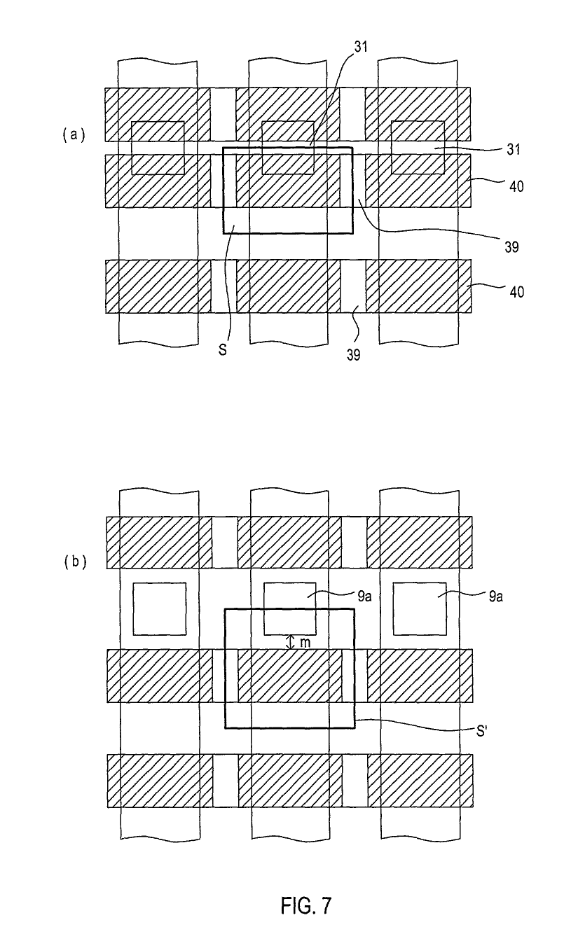

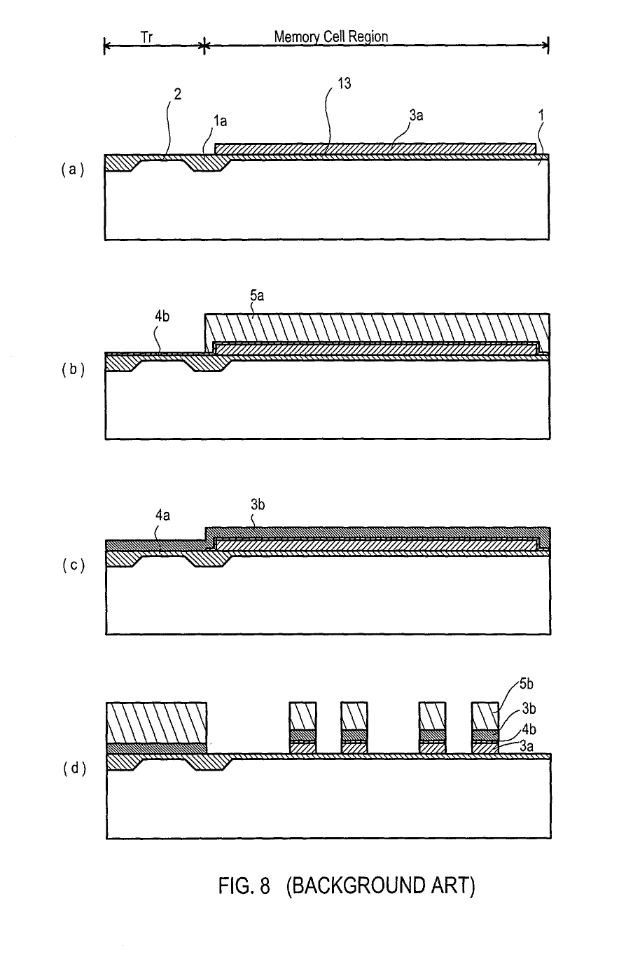

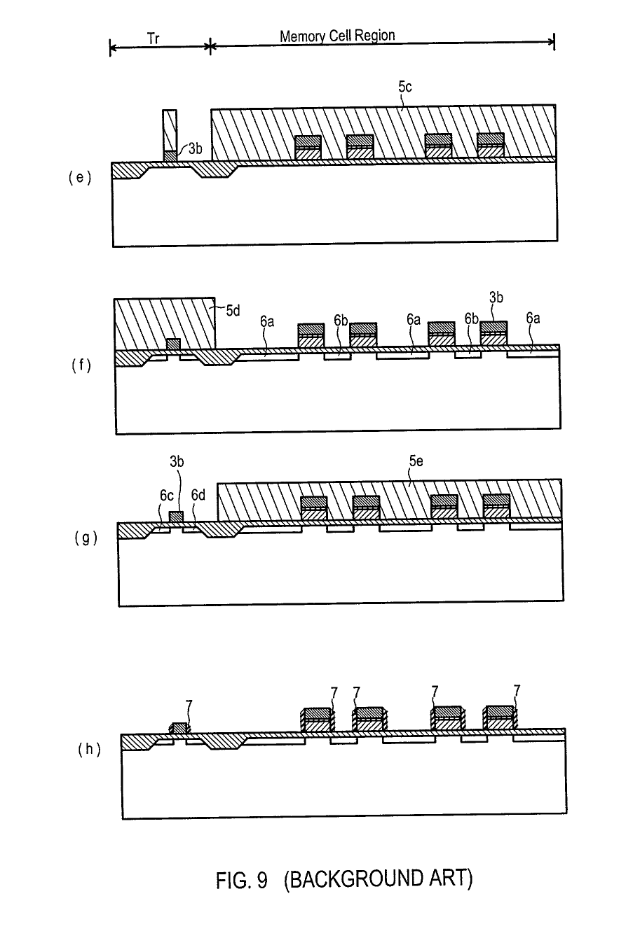

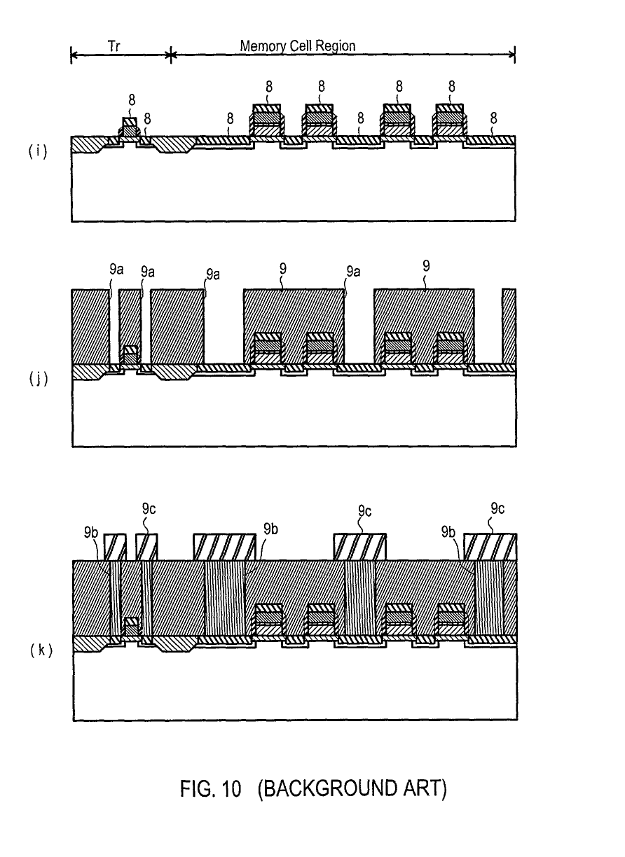

FIG. 7 illustrates the cell size of the non-volatile semiconductor memory device.

FIG. 7(a) is a plan view of a portion of a memory cell region of a non-volatile semiconductor memory device when manufacturing by a manufacturing method according to an embodiment of the present invention. FIG. 7(b) is a plan view of a portion of a memory cell region of a conventional non-volatile semiconductor memory device manufactured by a conventional manufacturing method.

As described above, a manufacturing method for a non-volatile semiconductor memory device in a flash memory process according to the present invention may simultaneously adopt a self-aligned contact using a self-alignment process for forming a drain contact and a salicide process in forming a metal silicide layer. In this way, the memory cell area may be reduced and the power supply voltage may be lowered.

More specifically, polycrystalline silicon at a gate portion in peripheral transistor region 10b may be formed at the same time a floating gate portion in memory cell region 10a is formed. Thereafter, self-aligned contacts may be formed on the side of drain regions 23 of two electrodes in memory cell region 10a. The entire surface may then be covered with a second nitride film 27 and an etch back may then be conducted. Diffusion layers of a gate electrode and source/drain region 26 of peripheral transistor region 10b may be changed to include a silicide layer by a salicide process.

Referring now to FIGS. 7(a) and 7(b), therefore, in non-volatile semiconductor memory device 10, as illustrated in FIG. 7(a), according to the present invention, cell contact holes 31 may be arranged so as to overlap a gate line side of control gates 39 and floating gates 40. Non-volatile semiconductor memory device 10 may include a cell size S that is the area of a memory cell. However, as illustrated in FIG. 7(b), a conventional non-volatile semiconductor memory device in which contact holes 9a are separated from the gate lines by a margin m may have a cell size S′. By providing cell contact holes 31 arranged so as to overlap the gate line side of control gates 39 and floating gates 40 cell size S in non-volatile semiconductor memory device 10 may be reduced and may be smaller than cell size S′ in the conventional non-volatile semiconductor memory device.

Margins m between cell contact holes 9a and gate lines may be included in the conventional semiconductor memory device. However, the present invention may not include a margin m between cell contact holes 31 and gate lines (39 and 40). In fact, conceptually, the present invention may include a margin m where (m≦0). By eliminating the need for a margin m, a distance between gate electrodes on a drain side may be narrowed.

Each side face (edge) of the gate electrodes may be an almost vertical surface because etch back may be conducted while covering the entire surface with second nitride film 27 after the self-aligned contacts are formed.

In this way, the present invention may include a manufacture of a semiconductor memory device 10 in a flash memory process in which metal silicide layers 28 may be formed on diffusion layers of memory cell region 10a and peripheral transistor region 10b and, at the same time, may form self-aligned contacts (SAC) in memory cell region 10a. Thus, it may be possible to reduce a size of memory cells while lowering a resistance of a peripheral transistor.

The self-aligned contact may be made possible by forming a gate electrode of the peripheral transistor and a floating gate electrode of a memory cell transistor from the same material and further forming an insulating film on a control gate electrode of a memory cell transistor.

As described above, the present invention may reduce cell area while lowering a resistance of a peripheral transistor. This may be accomplished by forming a metal silicide layers on diffusion layers of a memory cell transistor and a peripheral transistor as well as on a gate electrode of a peripheral transistor while contacts of a memory cell transistor have a self-aligned contact structure.

The above non-volatile semiconductor memory device may be obtained by a manufacture method for a non-volatile semiconductor memory device according to the present invention.

It is understood that the embodiments described above are exemplary and the present invention should not be limited to those embodiments. Specific structures should not be limited to the described embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A non-volatile semiconductor memory device including a memory cell transistor and peripheral transistor on the same substrate, comprising:
a metal suicide layer formed on at least one diffusion layer of the memory cell transistor, at least one diffusion layer of the peripheral transistor and on a gate electrode of the peripheral transistor; and
a self aligned contact structure providing an electrical connection to the at least one diffusion layer of the memory cell transistor.

2. The non-volatile semiconductor memory device according to claim 1, wherein:
the gate electrode of the peripheral transistor and a floating gate electrode of the memory cell transistor are formed from the same material.

3. The non-volatile semiconductor memory device according to claim 1, further including:
a gate insulating film formed under the gate of the peripheral transistor and floating gate insulating film under a floating gate electrode of the memory cell transistor wherein the gate insulating film is thicker than the floating gate insulating film.

4. The non-volatile semiconductor memory device according to claim 1, wherein:
the self aligned contact structure includes a conductive plug and the conductive plug includes a conductive plug portion at least partially overlapping a memory cell gate electrode of the memory cell transistor.

5. The non-volatile semiconductor memory device according to claim 1, further including:
an element separation region disposed between the peripheral transistor and the memory cell transistor.

6. The non-volatile semiconductor memory device according to claim 1, wherein:
the metal silicide layer includes cobalt.

7. A method of manufacturing a non-volatile semiconductor memory device having a memory cell transistor and a peripheral transistor on the same substrate, comprising the steps of:
forming a metal silicide layer on at least one diffusion layer of the memory cell transistor and at least one diffusion layer of the peripheral transistor at essentially the same time; and
forming a self aligned contact to provide an electrical connection to the at least one diffusion layer of the memory cell transistor.

8. The method of manufacturing a non-volatile semiconductor memory device according to claim 7, wherein:
forming a contact hole to provide an electrical connection to the at least one diffusion layer of the peripheral transistor, the contact hole being formed at essentially the same time as the self aligned contact.

9. The method of manufacturing a non-volatile semiconductor memory device according to claim 7, wherein:
the memory cell transistor includes a floating gate and a memory cell transistor control gate and the self aligned contact includes a conductive plug including a conductive plug portion at least partially overlapping the memory cell transistor control gate.

10. The method of manufacturing a non-volatile semiconductor memory device according to claim 9, further including:
Forming a side wall insulating film on a side of the memory cell transistor control gate.

11. A method of manufacturing a non-volatile semiconductor memory device having a memory cell transistor and a peripheral transistor on a semiconductor substrate, comprising the steps of:
forming an element separation region on the semiconductor substrate;
forming a first gate oxide film in a memory cell transistor region and a peripheral transistor region;
forming a peripheral transistor gate electrode and a memory cell transistor floating gate electrode;
forming an inter-electrode insulating film over the floating gate electrode;
forming a memory cell transistor control gate electrode over the inter-electrode insulating film;
forming a first nitride film over the memory cell transistor control gate electrode;
forming a peripheral diffusion electrode for the peripheral transistor and a memory cell diffusion electrode for the memory cell transistor;
forming a second nitride film as side walls on the side faces of the memory cell transistor control gate electrode;
forming metal silicide layers on the peripheral transistor gate electrode and peripheral transistor diffusion electrode;
sequentially forming a third nitride film and an interlayer insulating film over the memory cell transistor region and peripheral transistor region; and
removing portions of the interlayer insulating film and the third nitride film that are over the memory cell diffusion electrode to open a memory cell contact hole.

12. The method of manufacturing a non-volatile semiconductor memory device according to claim 11, wherein:
forming the peripheral transistor gate electrode and the memory cell transistor floating gate includes forming a first polycrystalline silicon film over the surface and patterning the first polycrystalline silicon film so as to separate the peripheral transistor region from the memory cell transistor region.

13. The method of manufacturing a non-volatile semiconductor memory device according to claim 12, wherein:
the steps of forming the interlayer electrode insulating film, forming the memory cell transistor control gate electrode, and forming the first nitride film include
forming the inter-electrode insulating film, a second polycrystalline silicon film, and the first nitride film in that order on the semiconductor substrate; and
etching the first nitride film, second polycrystalline film, and inter-electrode insulating film to form the memory cell transistor control gate electrode.

14. The method of manufacturing a non-volatile semiconductor memory device according to claim 13, wherein:
forming the memory cell transistor floating gate electrode includes etching the first polycrystalline silicon film in the memory cell transistor region in the step of etching the first nitride film, second polycrystalline film, and inter-electrode insulating film.

15. The method of manufacturing a non-volatile semiconductor memory device according to claim 14, wherein:
the second polycrystalline silicon film contains an impurity.

16. The method of manufacturing a non-volatile semiconductor memory device according to claim 15, wherein:
forming the peripheral diffusion electrode and the memory cell diffusion electrode includes a heat treatment.

17. The method of manufacturing a non-volatile semiconductor memory device according to claim 16, wherein:
forming the peripheral transistor gate electrode includes etching the first polycrystalline film in the peripheral transistor region separately from etching the first polycrystalline film in the memory cell transistor region.

18. The method of manufacturing a non-volatile semiconductor memory device according to claim 17, wherein:
removing portions of the interlayer insulating film and the third nitride layer includes removing portions of the interlayer insulating film and the third nitride layer over the peripheral transistor diffusion electrode to open a peripheral contact hole.

19. The method of manufacturing a non-volatile semiconductor memory device according to claim 18, further including the step of:
forming a second gate oxide film on the first gate oxide film in the peripheral transistor region while substantially leaving the first gate oxide film in the memory cell region.

20. The method of manufacturing a non-volatile semiconductor memory device according to claim 11, wherein:
the non-volatile semiconductor memory device is a flash memory.
